(19) United States
(12) Patent Application Publication
(10) Pub. No.: US 2018/0294144 A1
(43) Pub. Date: Oct. 11, 2018

(54) HIGH DEPOSITION RATE HIGH QUALITY SILICON NITRIDE ENABLED BY REMOTE NITROGEN RADICAL SOURCE

(71) Applicant: Applied Materials, Inc., Santa Clara, CA (US)

(72) Inventors: Joseph F. AUBUCHON, San Jose, CA (US); Nattaworn NUNTAWORANUCH, Stanford, CA (US); Yi YANG, San Jose, CA (US); Truong NGUYEN, Milpitas, CA (US); Karthik JANAKIRAMAN, San Jose, CA (US); Sanjeev BALUJA, Campbell, CA (US)

(21) Appl. No.: 15/939,363

(22) Filed: Mar. 29, 2018

Related U.S. Application Data
(60) Provisional application No. 62/483,798, filed on Apr. 10, 2017.

(51) Int. Cl. H01J 37/32; H01L 21/02; C23C 16/513; C23C 16/455; C23C 16/34

(52) U.S. Cl. CPC H01J 37/32357; H01L 21/0217; H01L 21/02274; H01J 37/3244; H01J 2237/332; H01J 37/32091; C23C 16/513; C23C 16/455; C23C 16/345; H01J 37/32422

(57) ABSTRACT

Implementations of the disclosure relate to a processing system. In one implementation, the processing system includes a lid, a gas distribution plate disposed below the lid, the gas distribution plate having through holes arranged across the diameter of the gas distribution plate, a pedestal disposed below the gas distribution plate, the pedestal and the gas distribution plate defining a plasma excitation region therebetween, a first RPS unit having a first gas outlet coupled to a first gas inlet disposed at the lid, the first gas outlet being in fluid communication with the plasma excitation region, and a second RPS unit having a second gas outlet coupled to a second gas inlet disposed at the lid, wherein the second gas outlet is in fluid communication with the plasma excitation region, and the second RPS unit has an ion filter disposed between the second gas outlet and the second gas inlet.

### CROSS-REFERENCE TO RELATED APPLICATION

This application claims benefit of United States provisional patent application Ser. No 62/483,798, filed on Apr. 10, 2017, which is herein incorporated by reference.

### BACKGROUND

### Field

Implementations of the present disclosure generally relate to an apparatus for processing substrates in a semiconductor substrate process chamber.

### Description of the Related Art

Memory devices, such as 3-dimension vertical NAND (V-NAND) memory devices, may include vertical structures having alternating layers of oxide and nitride (ONON) on a silicon substrate. High-aspect ratio openings may be formed between each of the vertical structures. The high-aspect ratio openings may be filled with metal to create electrical contacts in the memory device.

The deposition of oxides and nitrides can be performed in the same deposition chamber for higher throughput and better utilization of the deposition chamber. However, deposition of any given oxides or nitrides involves a unique pressure, electrode spacing, plasma power, gas flow ratio, and substrate temperature. Therefore, the overall throughput is often compromised due to changes in the parameters for different films during the deposition and the transition stage between the depositions. Particularly, the deposition time for the silicon nitrides has been observed to be the main cause for the decrease of the overall throughput.

Therefore, there is a need in the art for an improved apparatus that can increase the deposition rate for nitrides while maintaining the desired film properties.

### SUMMARY

Implementations of the disclosure relate to a plasma processing system combining a primary plasma source, such as a capacitively coupled plasma (CCP) source or an inductively coupled plasma (ICP) source, and a secondary plasma source, such as a remote plasma source (RPS). In one implementation, a substrate processing system is provided. The processing system includes a lid, a gas distribution plate disposed below the lid, the gas distribution plate having through holes arranged across the diameter of the gas distribution plate, a pedestal disposed below the gas distribution plate, the pedestal and the gas distribution plate defining a plasma excitation region therebetween, a first RPS unit having a first gas outlet coupled to a first gas inlet disposed at the lid, the first gas outlet being in fluid communication with the plasma excitation region, and a second RPS unit having a second gas outlet coupled to a second gas inlet disposed at the lid, wherein the second gas outlet is in fluid communication with the plasma excitation region, and the second RPS unit has an ion filter disposed between the second gas outlet and the second gas inlet of the lid.

In another implementation, a substrate processing system includes a plasma source unit comprising a lid and a dual channel gas distribution plate disposed relatively below the lid, the dual channel gas distribution plate having a first set of channels that traverse the thickness of the dual channel gas distribution plate, the first set of channels being arranged across the diameter of the dual channel gas distribution plate, and a second set of channels disposed within the dual channel gas distribution plate, the second set of channels traversing a portion of the thickness of the dual channel gas distribution plate. The substrate processing system also includes a pedestal disposed below the dual channel gas distribution plate, the pedestal and the dual channel gas distribution plate defining a plasma excitation region therebetween, a first remote plasma source (RPS) unit having a first gas outlet coupled to a first gas inlet disposed at the lid, the first gas outlet being in fluid communication with the plasma excitation region, and a second RPS unit having a second gas outlet coupled to a second gas inlet disposed at the lid, wherein the second gas outlet is in fluid communication with the plasma excitation region, and the second RPS unit has an ion filter disposed between the second gas outlet and the second gas inlet of the lid.

In yet another implementation, a substrate processing system comprises a lid, a gas distribution plate disposed relatively below the lid, the gas distribution plate having a plurality of through holes arranged across the diameter of the gas distribution plate, an ion suppression element disposed relatively below the gas distribution plate, the ion suppression element having a plurality of through holes each having a tapered portion and a cylindrical portion, the ion suppression element and the gas distribution plate defining a first plasma excitation region, a dual channel gas distribution plate disposed relatively below the ion suppression element, the dual channel gas distribution plate having a first set of channels that traverse the thickness of the dual channel gas distribution plate, the first set of channels arranged across the diameter of the dual channel gas distribution plate, a second set of channels disposed within the dual channel gas distribution plate, the second set of channels traversing a portion of the thickness of the dual channel gas distribution plate.

The substrate processing system also includes a plasma suppressor disposed between the ion suppression element and the dual channel gas distribution plate, the plasma suppressor having a plurality of through holes disposed across the diameter of the plasma suppressor, a pedestal disposed below the dual channel gas distribution plate, the pedestal and the dual channel gas distribution plate defining a second plasma excitation region therebetween, a first gas source coupled to a first gas inlet disposed at the lid, wherein the first gas inlet is in fluid communication with the first plasma excitation region, and a second gas source coupled to a second gas inlet disposed at a sidewall of the substrate processing system.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 shows a schematic cross-sectional of a processing system according to one implementation of the present disclosure.

FIG. 2 shows a schematic cross-sectional of a processing system according to another implementation of the present disclosure.

FIG. 3 shows a schematic cross-sectional of a processing system according to yet another implementation of the present disclosure.

To facilitate understanding, identical reference numerals have been used, where possible, to designate identical elements that are common to the figures. It is contemplated that elements disclosed in one implementation may be beneficially utilized on other implementations without specific recitation.

### DETAILED DESCRIPTION

Implementations of the disclosure relate to a hybrid plasma processing system combining a primary plasma source, such as capacitively coupled plasma (CCP) source or inductively coupled plasma (ICP) source, and a secondary plasma source, such as remote plasma source (RPS). The primary plasma source may be positioned adjacent to a substrate processing region and the secondary plasma source may be positioned further away from the substrate processing region. In one implementation, the primary plasma source is positioned between the substrate processing region and the secondary plasma source. While CCP unit is described in this disclosure as an example for the primary plasma source, any plasma source using low-pressure discharge such as inductively coupled plasma (ICP) source, or using atmospheric pressure discharge such as capacitive discharge, or any other suitable plasma source can be used interchangeably in implementations described herein. Details of the disclosure and various implementations are discussed below.

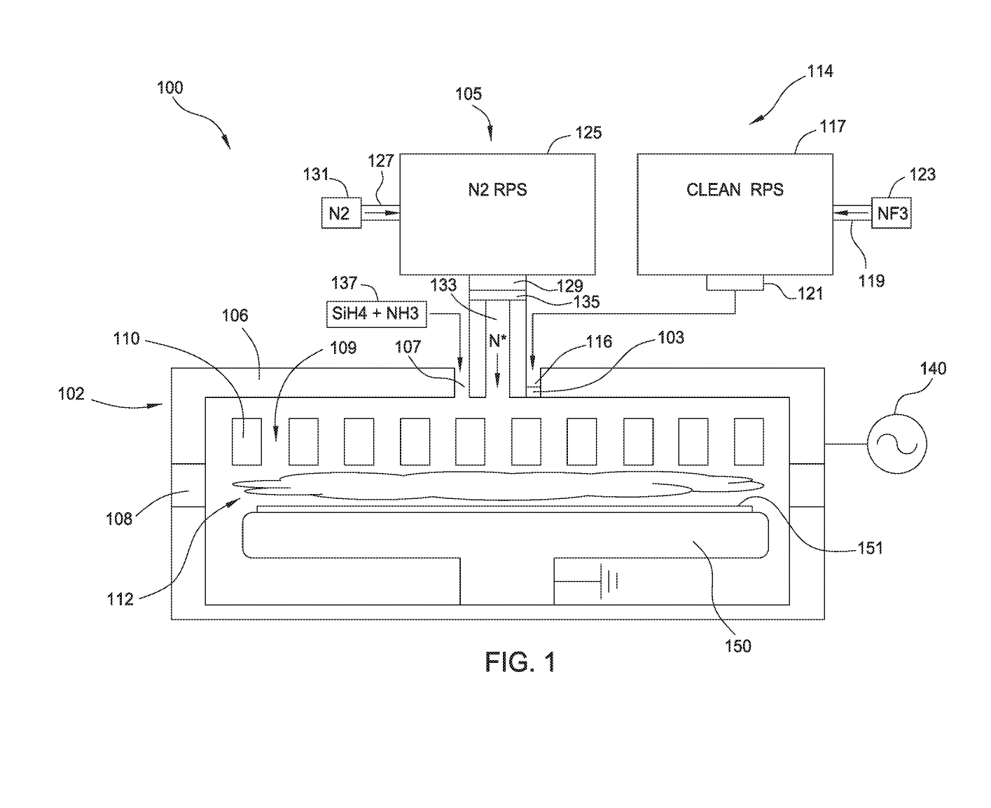

FIG. 1 shows a schematic cross-sectional of a processing system 100 according to one implementation of the present disclosure. The processing system 100 generally includes a capacitively coupled plasma (CCP) unit 102, a first remote plasma source (RPS) unit 114 coupled to the CCP unit 102, and a second RPS unit 105 coupled to the CCP unit 102. The processing system 100 may hold an internal pressure different than the the ambient environment of the fabrication facility. For example, the pressure inside the processing system 100 may be about 10 mTorr to about 20 Torr.

The CCP unit 102 can be functioned as a first plasma source inside the processing system 100. The CCP unit 102 generally includes a lid 106 and a gas distribution plate 110 disposed relatively below the lid 106. The gas distribution plate 110 has a plurality of through holes 109 arranged across the diameter of the gas distribution plate 110 to allow uniform delivery of the gas into the plasma excitation region 112. The lid 106 and the gas distribution plate 110 may be made of highly doped silicon or metal, such as aluminum, stainless steel, etc. The lid 106 and the gas distribution plate 110 may be coated with a protective layer including alumina or yttrium oxide. In some implementations, the lid 106 and the gas distribution plate 110 are electrically conductive electrodes that can be electrically biased with respect to each other to generate an electric field strong enough to ionize gases between the lid 106 and the gas distribution plate 110 into a plasma.

A plasma generating gas mixture may be supplied to the CCP unit 102 from a gas source 137 through a first gas inlet 107. The first gas inlet 107 may be disposed at the lid 106. In one implementation where a silicon-containing layer, for example silicon nitride, is to be formed on the substrate, the gas source 137 may include a silicon-containing precursor and a nitrogen-containing precursor. Suitable silicon-containing precursor may include silanes, halogenated silanes, organosilanes, and any combinations thereof. Silanes may include silane (Si₂H₆) and higher silanes with the empirical formula SiₓH₍₂ₓ₊₂₎, such as disilane (Si₂H₆), trisilane (Si₃H₈), and tetrasilane (Si₄H₁₀), or other higher order silanes such as polychlorosilane. Suitable nitrogen-containing precursor may include nitrogen (N₂), nitrous oxide (N₂O), nitric oxide (NO), nitrogen dioxide (NO₂), ammonia (NH₃), and any combination thereof. In one implementation, the gas source 131 includes N₂. In one implementation, the silicon-containing precursor is SiH₄ and the nitrogen-containing precursor is N₂.

The processing system 100 also includes a pedestal 150 that is operable to support and move the substrate 151 (e.g., a wafer substrate). The pedestal 150 may be grounded. The distance between the pedestal 150 and the gas distribution plate 110 define the plasma excitation region 112. The pedestal 150 may be vertically or axially adjustable within the processing chamber 100 to increase or decrease the plasma excitation region 112 and effect the deposition or etching of the substrate by repositioning the substrate 151 with respect to the gases passed through the gas distribution plate 110. In some cases, the pedestal 150 may be rotatable to help uniform distribution of the deposition/etching chemistry on the substrate. The pedestal 150 may have a heat exchange channel (not shown) through which a heat exchange fluid (e.g., water) flows to control the temperature of the substrate. Circulation of the heat exchange fluid allows the substrate temperature to be maintained at relatively low temperatures (e.g., about −20° C. to about 90° C.). The pedestal 150 may also be configured with a heating element (such as a resistive heating element) embedded therein to maintain the substrate at desired heating temperatures (e.g., about 90° C. to about 1100° C.).

An electrical insulator 108 may be disposed between the lid 106 and the gas distribution plate 110 to prevent them from short circuiting when a plasma is generated. A power supply 140 is electrically coupled to the CCP unit 102 to provide electrical power (e.g., RF power) to the lid 106, the gas distribution plate 110, or both, to generate a plasma in the plasma excitation region 112. The power supply 140 may be configured to deliver an adjustable amount of power to the CCP unit 102 depending on the process performed. The power supply 140 is operable to create an adjustable voltage in the gas distribution plate 110 to adjust an ion concentration of the activated gas in the plasma excitation region 112. In some cases, electrical power may be applied to the lid 106 while the gas distribution plate 110 is grounded.

To enable the formation of a plasma in the plasma excitation region 112, the insulator 108 may electrically insulate the lid 106 and the gas distribution plate 110. The insulator 108 may be made from a ceramic material and may have a high breakdown voltage to avoid sparking. If desired, the CCP unit 102 may further include a cooling unit (not shown) that includes one or more cooling fluid channels to cool surfaces of chamber components exposed to the plasma with a circulating coolant (e.g., water).

The first RPS unit 114 may be functioned as a second plasma source inside the processing system 100. The first RPS unit 114 includes a container 117 where a plasma of ions, radicals, and electrons is generated. The container 117 has a gas inlet 119 disposed at one end of the container 117 and a gas outlet 121 disposed at the other end of the container 117. The gas inlet 119 is coupled to a gas source 123. The gas source 123 may contain any suitable gas or gas mixture. In cases where chamber cleaning is desired, the gas source 123 may include a fluorine-containing gas, such as NF₃, CF₄, C₂F₆, or SF₆, etc. The gas outlet 121 is in fluid communication with the plasma excitation region 112 through a second gas inlet 116. The second gas inlet 116 may be disposed at the lid 106. During processing, the plasma can travel from the first RPS unit 114 through the second gas inlet 116 and into the plasma excitation region 112.

The first RPS unit 114 may be coupled to an energy source (not shown) which provides an excitation energy to excite the process gas (from the gas source 123) into a plasma. The energy source may energize the process gas by microwave, thermal, UV, RF, electron synchrotron radiation, or any suitable approach. The energized process gas(es) from the first RPS unit 114 may be used to clean the process residues inside the CCP unit 102, strike a plasma in the plasma excitation region 112, or may maintain a plasma that has already been formed in the plasma excitation region 112. In some implementations, the process gas(es) may have already been converted (or at least partially converted) into plasma excited species in the first RPS unit 114 before traveling downstream though the gas inlet 116 to the CCP unit 102. The RPS plasma excited species may include ionically-charged plasma species as well as neutral and radical species. When the plasma excited species reach the plasma excitation region 112, they may be further excited in the CCP unit 102, or the plasma excited species may pass through the gas distribution plate 110 to the plasma excitation region 112 without further excitation.

Optionally, an appropriate ion filter 103, such as electrostatic filters, wire or mesh filters, or magnetic filters, may be disposed between the first RPS unit 114 and the CCP unit 102 to eliminate the majority or substantially all of the ions in the plasma such that only radicals of the plasma flow to the CCP unit 102. In some cases, the CCP unit 102 may be turned on with small amount of power to boost radical regeneration to compensate radical loss due to the flow path, or to change radical composition by using different RF frequency and other parameters. Alternatively, the electrodes of the CCP unit 102 may not be powered so that the radicals of the plasma from the first RPS unit 114 bypass the gas distribution plate 110 to avoid or minimize undesired reaction occurred in the plasma excitation region 112.

The second RPS unit 105 is functioned as a radical source for the processing system 100. In one embodiment, the second RPS unit 105 is used to provide nitrogen radical source. The incorporation of the nitrogen radical source (i.e., the second RPS unit 105) to the CCP unit 102 can significantly increase the deposition rate of the SiN film since more radical nitrogen species are provided in the plasma excitation region 112 for the surface reaction. As discussed previously in the background, the overall throughput is often compromised due to changes in the parameters for different films during the deposition and the transition stage between the depositions. Particularly, the deposition time for the silicon nitrides has been observed to be the main cause for the decrease of the overall throughput. While the nitride deposition rate may be increased by increasing the flow of the processing gas (e.g., SiH₄), power, and pressure, the film properties such as uniformity suffer due to the increased concentration of Si—H bonds in the deposited nitrides, which are believed to easily lose hydrogen to form a dangling bond.

Incorporating the second RPS unit 105 to the processing system 100 can increase the deposition time for the silicon nitrides without sacrificing quality of the deposited film properties. Particularly, the deposited SiN films can be formed with low Si—H bonds (thus low hydrogen content in the films). Low hydrogen content in the deposited SiN film leads to a reduced intrinsic stress (delta stress). SiN films formed with a reduced intrinsic stress can prevent film shrinkage during the subsequent thermal process. In contrast, SiN films having a high intrinsic stress may shrink and bend an underlying thin substrate by a measurable degree, which renders the substrate concave or convex. The addition of the second RPS unit 105 can reduce the number of Si—H bonds in the SiN film because the second RPS unit 105 provides abundant nitrogen radicals to promote preferential reaction with silicon and hydrogen from the gas mixture, thereby reducing Si—H bonds in the deposited film. For example, during the deposition, the plasma generating gas mixture (e.g., SiH₄ and NH₃) from the gas source 137 is flowed to the CCP unit 102 through the first gas inlet 107. The excitation of the gas mixture may produce SiH₃, SiH₂, SiH, NH₂, and NH etc. in ionic state in the plasma excitation region 112. The radical nitrogen species (e.g., N radicals) generated from the second RPS unit 105 can react preferentially with silicon due to lower Si—Si bond energies (222 kJ/mol) as compared to Si—N bond energies (343 kJ/mol). The radical nitrogen species can also react preferentially with hydrogen because the SiH₃—H bond energies (378 kJ/mol) is lower than NH₂—H bond energies (435 kJ/mol). Therefore, the amount of hydrogen available for the surface reaction of silicon nitride is reduced. The addition of the radical nitrogen species to the excited gas mixture during deposition thus encourages replacement of the Si—H bonds with Si—N and N—H bonds, which in turn reduces the concentration of Si—H bonds in the deposited SiN film. As a result, the deposited SiN film can be formed with improved film quality since the number of dangling bonds at the deposited SiN film surface is reduced.

Deposition of the silicon nitride film may be performed by the following process conditions. The process chamber (e.g., the CCP unit 102) may be maintained at a pressure of about 1 Torr to about 10 Torr. A source power from an energy source coupling to the second RPS unit 105 (used to excite the process gas from the gas source 131 into a plasma) may be provided at about 1200 watts (W) to about 2500 W. The source power may be applied at a radio frequency (RF) range of about 10 MHz to about 60 MHz. The electrode spacing of the CCP unit 102 may be about 600 mils to about 1200 mils. A plasma generating gas mixture of SiH₄ and NH₃ may be introduced into the CCP unit 102. The gas flow of SiH₄ may be about 100 sccm to about 500 sccm, and the gas flow of NH₃ may be about 2000 sccm to about 5000 sccm. The nitrogen-containing gas, for example N₂, may be introduced into the second RPS unit 105. The gas flow of N₂ may be about 850 sccm to about 1800 sccm. A carrier gas, such as helium, may be flowed with the plasma generating gas mixture, and the gas flow of He may be about 3500 sccm to about 8000 sccm. The total process flow may be about 8000 sccm to about 16000 sccm. The deposition rate is about 3500 Å/min or above, for example about 3800 Å/min to about 5000 Å/min.

Table I below lists three separate process conditions for deposition of silicon nitride films. Film #1 and #2 are SiN deposited with the RPS (i.e., second RPS unit 105) turning on. Film #3 is SiN deposited with the RPS turning off. Table II below shows the stress and FTIR spectra of the deposited Film #1, #2, and #3. FTIR spectra represent percentage of Si—H to Si—N.

TABLE I

| | | | | | | | | Total | |
|---|---|---|---|---|---|---|---|---|---|
| | | | | | | | | process | |
| | RF | Pressure | Spacing | SiH₄ | NH₃ | He | N₂ | flow | |
| Film# | (W) | (Torr) | (mil) | (sccm) | (sccm) | (sccm) | (sccm) | (sccm) | RPS |
| 1 | 1700 | 5.5 | 900 | 210 | 3500 | 5000 | 2000 | 10710 | On |
| 2 | 1900 | 5.5 | 900 | 210 | 3500 | 5000 | 1330 | 10040 | On |
| 3 | 1900 | 5.5 | 900 | 210 | 3500 | 5000 | 1330 | 10040 | Off |

TABLE II

| | | FTIR [%] | FTIR [%] | FTIR [%] |
|---|---|---|---|---|
| Film# | Stress | (Center) | (70 mm) | (140 mm) |
| 1 | 349.66 | 0 | 0.09 | 0.01 |
| 2 | 235.88 | 0.02 | 0.07 | 0 |
| 3 | 270.79 | 0.02 | 0.14 | 0.06 |

As can be seen in Table I and Table II, the SiN Film #1 and #2 were deposited under similar process conditions except that the SiN Film #1 were deposited using a lower RF power and higher flow rate of nitrogen. While the SiN Film #1 and #2 were deposited with the RPS On (i.e., introducing radical nitrogen species from the second RPS unit 105), the SiN Film #2 has a lower intrinsic stress, suggesting that the increased RF power can result in lower hydrogen content in the deposited SiN films, even though more nitrogen was provided during deposition of the SiN Film #1. In addition, the SiN Film #2 in Table II shows a reduced intrinsic stress when compared to the SiN Film #3, suggesting that the introduction of radical nitrogen species from the second RPS unit 105 can reduce the concentration of Si—H bonds in the deposited SiN film. Likewise, the FTIR spectra at various locations of the deposited SiN film also show the SiN Film #2 has lower percentage of Si—H to Si—N as compared to the SiN Film #3.

The second RPS unit 105 may include a container 125 where a plasma of ions, radicals, and electrons is generated. The container 125 may have a gas inlet 127 disposed at one end of the container 125 and a gas outlet 129 disposed at the other end of the container 125. The gas outlet 129 is in fluid communication with the plasma excitation region 112 through a third gas inlet 133. The third gas inlet 133 may be disposed at the lid 106. The gas inlet 127 is coupled to a gas source 131. The gas source 131 may contain any suitable gas or gas mixture. In cases where a nitrogen-containing material is to be formed on the substrate, the gas source 131 may include a nitrogen-containing gas, such as nitrogen (N₂), nitrous oxide (N₂O), nitric oxide (NO), nitrogen dioxide (NO₂), ammonia (NH₃), and any combination thereof. In one implementation, the gas source 131 includes N₂.

The second RPS unit 105 may be coupled to an energy source (not shown) which provides an excitation energy to excite the process gas from the gas source 131 into a plasma. The energy source may energize the process gas by microwave, thermal, UV, RF, electron synchrotron radiation, or any suitable approach. In cases where the gas source 131 contains N₂, the energetic excitation of N₂ produces N* radicals, positively charged ions such as N⁺ and N₂⁺, and electrons in the second RPS unit 105.

An ion filter 135 is disposed between the second RPS unit 105 and the CCP unit 102. The ion filter 135 may be disposed at any position along the length of the third gas inlet 133 to eliminate the majority or substantially all of the ions in the plasma flowing through the third gas inlet 133 such that only radicals of the plasma are flowed into the plasma excitation region 112. The ion filter 135 may be any suitable ion filter, such as electrostatic filters, wire or mesh filters, or magnetic filters. The use of the ion filter 135 allows the second RPS unit 105 to provide radical containing precursor, such as nitrogen-containing radicals, into the plasma excitation region 112 through the third gas inlet 133.

While the processing chamber 100 is shown with a single CCP unit 102, it is contemplated that the single CCP unit 102 may be replaced with a tandem processing chamber. That is, the CCP unit 102 may be two individual, separated CCP units sharing the first RPS unit 114 and the second RPS unit 105. In such a case, a housing may be used to cover a respective one of the tandem CCP units. The two individual CCP units may be positioned adjacent to each other in a symmetrical or asymmetrical manner. The two individual CCP units and the first and second RPS units 114, 105 further increase the overall throughput of the process.

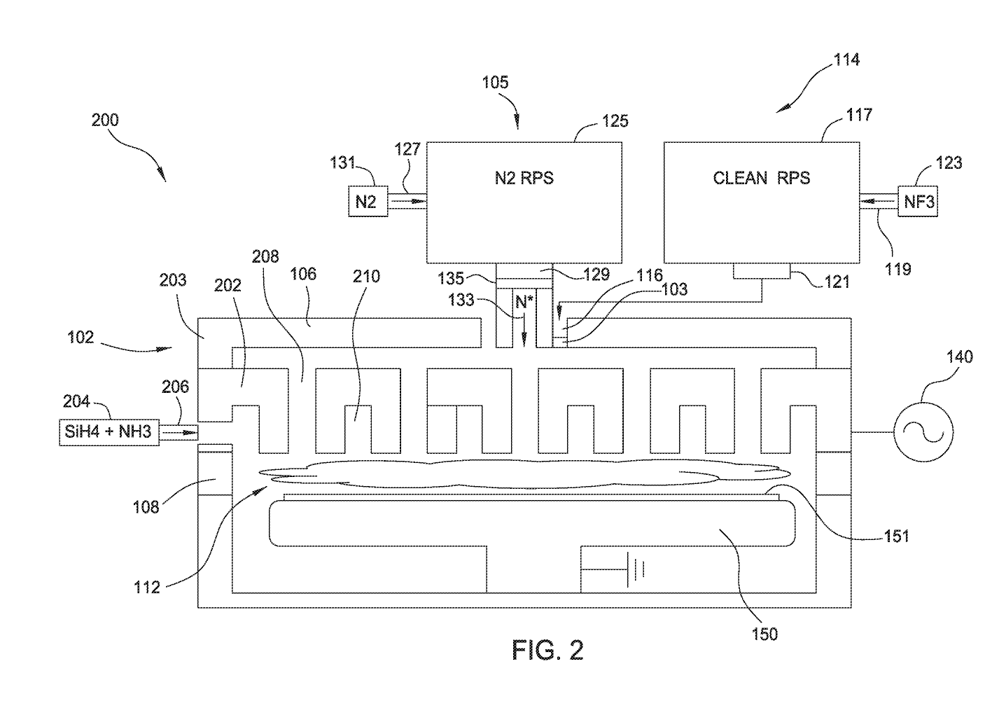

FIG. 2 shows a schematic cross-sectional of a processing system 200 according to another implementation of the present disclosure. The processing system 200 is similar to the processing system 100 except that the first gas inlet 107 is modified to be disposed at the sidewall 203 of the CCP unit 102. In addition, the gas distribution plate 110 of the processing system 100 is also replaced with a dual channel gas distribution plate 202. The dual channel gas distribution plate 202 is configured to permit the passage of the gas(es) coming from the first and second RPS units 114, 105 and the gas(es) coming from a gas source 204 through a sidewall gas inlet 206 disposed at the sidewall of the CCP unit 102. Similarly, the processing system 200 also includes the CCP unit 102, the first RPS unit 114 coupled to the CCP unit 102, and the second RPS unit 105 coupled to the CCP unit 102. Detail descriptions of the CCP unit 102, first and second RPS units 114, 105, and components associated therewith can be found above with respect to FIG. 1.

In this implementation, the dual channel gas distribution plate 202 is disposed relatively below the lid 106. The dual channel gas distribution plate 202 includes a first set of channels 208 that traverse the thickness of the dual channel gas distribution plate 202. The first set of channels 208 is arranged across the diameter of the dual channel gas distribution plate 202 to allow uniform delivery of the gas into the plasma excitation region 112. The dual channel gas distribution plate 202 also includes a second set of channels 210 disposed within the dual channel gas distribution plate 202. The second set of channels 210 may not traverse the thickness of the dual channel gas distribution plate 202. Therefore, the second set of channels 210 are not in fluid communication with the first and second RPS units 114, 105. Instead, the second set of channels 210 are fluidly coupled to the gas source 204 through the sidewall gas inlet 206.

The first and second sets of channels 208, 210 prevent the radical nitrogen species from the second RPS unit 105 and gas/precursor mixture from the gas source 204 from combining until they reach the plasma excitation region 112. In some implementations, the second set of channels 210 may have an annular shape at the opening facing the plasma excitation region 112, and these annular openings may be concentrically aligned around the circular openings of the first set of channels 208.

In cases where a silicon-containing layer, for example silicon nitride, is to be formed on the substrate, the gas source 204 may include a silicon-containing precursor and a nitrogen-containing precursor. Suitable silicon-containing precursor and nitrogen-containing precursor are discussed above with respect to FIG. 1. In one example, the silicon-containing precursor is silane and the nitrogen-containing precursor is NH₃. However, the contents of the gas sources 123, 131 and 204 may vary depending on the process performed.

During deposition, radical containing precursor, such as nitrogen-containing radicals, is introduced into the plasma excitation region 112 from the second RPS unit 105 through the third gas inlet 133. Sequentially or concurrently, a second gas, such as a gas mixture of a silicon-containing precursor (e.g., SiH₄) and a nitrogen-containing precursor (e.g., NH₃), is introduced from the gas source 204 to the plasma excitation region 112 through the sidewall gas inlet 206 and the second set of channels 210. The excitation of the second gas may produce SiH₃, SiH₂, SiH, NH₂, and NH etc. in ionic state in the plasma excitation region 112. The radical nitrogen species generated from the second RPS unit 105 react preferentially with silicon due to lower Si—Si bond energies (222 kJ/mol) as compared to Si—N bond energies (343 kJ/mol). The radical nitrogen species can also react with hydrogen because the SiH₃—H bond energies (378 kJ/mol) is lower than NH₂—H bond energies (435 kJ/mol). Therefore, the amount of hydrogen available to the surface reaction of silicon nitride is reduced. The addition of the radical nitrogen species to the excited gas mixture using the configuration of FIG. 2 can also encourage replacement of the Si—H bonds with Si—N and N—H bonds, which in turn reduces the concentration of Si—H bonds in the deposited SiN film. As a result, the deposited SiN film is formed with lower intrinsic stress. The incorporation of the nitrogen radical source (i.e., second RPS unit 105) to the CCP unit 102 significantly increase the deposition rate of the SiN film since more radical nitrogen species are provided in the plasma excitation region 112 for the surface reaction.

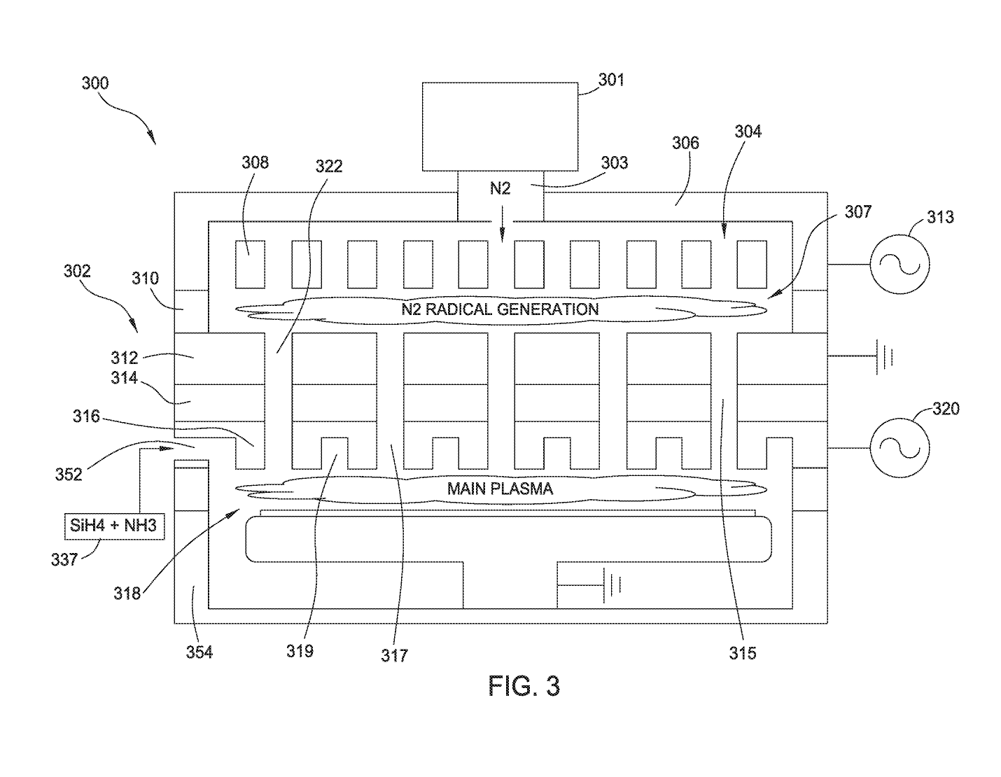

FIG. 3 shows a schematic cross-sectional of a processing system 300 according to yet another implementation of the present disclosure. The processing system 300 generally includes a capacitively coupled plasma (CCP) unit 302 and an in-situ plasma source unit 304 disposed atop the CCP unit 302. The CCP unit 302 functions to generate a first plasma source inside the processing system 300. The in-situ plasma source unit 304 generally includes a lid 306 and a gas distribution plate 308 disposed relatively below the lid 306. The gas distribution plate 308 has a similar construction to the gas distribution plate 110 as discussed above with respect to FIG. 1.

The in-situ plasma source unit 304 also has a gas source 301 coupled to the lid 306 through a gas inlet 303, which may be disposed at the lid 306. The gas source 301 may contain any suitable gas or gas mixture. In cases where a nitrogen-containing material is to be formed on the substrate, the gas source 301 may include a nitrogen-containing gas, such as nitrogen (N₂), nitrous oxide (N₂O), nitric oxide (NO), nitrogen dioxide (NO₂), ammonia (NH₃), and any combination thereof. In one implementation, the gas source 301 includes N₂. The nitrogen-containing gas flows through the through holes of the gas distribution plate 308 to a first plasma excitation region 307 defined between the gas distribution plate 308 and an ion suppression element 312.

The in-situ plasma source unit 304 may optionally include an ion suppression element 312 disposed relatively below the gas distribution plate 308. The lid 306 and/or the gas distribution plate 308 may be coupled to a RF generator 313 that provides RF power to the lid 306 and/or the gas distribution plate 308. The ion suppression element 312 may be grounded. The lid 306 and/or the gas distribution plate 308 supplied with an RF power may serve as a cathode electrode, while the grounded ion suppression element 312 may serve as an anode electrode. The lid 306 and/or the gas distribution plate 308 and the ion suppression element 312 are operated to form an RF electric field in the first plasma excitation region 307 (i.e., the region between the gas distribution plate 308 and the ion suppression element 312). The RF electric field ionizes the process gas(es) from the gas source 301 into a plasma in the first plasma excitation region 307.

The ion suppression element 312 generally includes a plurality of through holes 322 that are configured to suppress the migration of ionically-charged species out of the first plasma excitation region 307 while allowing uncharged neutral or radical species to pass through the ion suppression element 312 into a second plasma excitation region 318. These uncharged species may include highly reactive species that are transported with less reactive carrier gas through the through holes 322. Therefore, the migration of ionic species through the through holes 322 may be reduced, and in some instances completely suppressed. Controlling the amount of ionic species passing through the ion suppression element 312 provides increased control over the gas mixture brought into contact with the underlying substrate, which in turn increases control of the deposition characteristics of the gas mixture. The ion suppression element 312 may be made of highly doped silicon or metal, such as aluminum, stainless steel, etc. In one implementation, the through holes 322 may include a tapered portion that faces the second plasma excitation region 318, and a cylindrical portion that faces the first plasma excitation region 307.

A first electrical insulator 310, similar to the electrical insulator 108 as discussed above with respect to FIG. 1, is disposed between the ion suppression element 312 and the gas distribution plate 308.

A dual channel gas distribution plate 316, such as the dual channel gas distribution plate 202 as discussed above with respect to FIG. 2, is disposed relatively below the ion suppression element 312. The dual channel gas distribution plate 316 may be considered as part of the CCP unit 302. The dual channel gas distribution plate 316 includes a first set of channels 317 that traverse the thickness of the dual channel gas distribution plate 316. The first set of channels 317 is arranged across the diameter of the dual channel gas distribution plate 316 to allow uniform delivery of the gas into the second plasma excitation region 318. The dual channel gas distribution plate 316 also includes a second set of channels 319 disposed within the dual channel gas distribution plate 316. The second set of channels 319 may not traverse the thickness of the dual channel gas distribution plate 316. Therefore, the second set of channels 319 are not in fluid communication with the first plasma excitation region 307. Instead, the second set of channels 319 are fluidly coupled to a gas source 337 through a sidewall gas inlet 352 disposed at the sidewall 354 of the CCP unit 302.

The first and second sets of channels 317, 319 prevent the radical nitrogen species from the first plasma excitation region 307 and gas/precursor mixture from the gas source 337 from combining until they reach the second plasma excitation region 318. In some implementations, one or more of the through holes 322 in the ion suppression element 312 may be aligned with one or more of the first set of channels 317 and the through holes 315 of a plasma suppressor 314 to allow at least some of the plasma excited species to pass through the through holes 322, the first set of channel 317, and through holes 315 without altering their direction of flow. In some implementations, the second set of channels 319 may have an annular shape at the opening facing the second plasma excitation region 318, and these annular openings may be concentrically aligned around the circular openings of the first set of channels 317.

A plasma suppressor 314 is optionally disposed between the ion suppression element 312 and the dual channel gas distribution plate 316. The plasma suppressor 314 has a plurality of through holes 315 disposed across the diameter of the plasma suppressor 314. The dimension and cross-sectional geometry of each of the through holes 315 are configured to prevent significant backflow of plasma from the second plasma excitation region 318 back into the first plasma excitation region 307. Particularly, the through holes 315 are dimensioned to allow the passage of gas to the dual channel gas distribution plate 316 but are small enough to prevent the creation of a plasma discharge therein. For example, each of the through holes 315 may have a diameter of about 0.050″. In this way, plasma discharge is generally prevented from existing within the first set of channels 317 past the plasma suppressor 314.

A pedestal 350, such as the pedestal 150 discussed above with respect to FIG. 1, is disposed relatively below the dual channel gas distribution plate 316. The pedestal 350 may be considered as part of the CCP unit 302. The pedestal 350 may be grounded. The dual channel gas distribution plate 316 may be coupled to a RF generator 320 and function as a cathode electrode, while the grounded pedestal 350 may serve as an anode electrode. The dual channel gas distribution plate 316 and the grounded pedestal 350 are operated to form an RF electric field in the plasma excitation region 318 (i.e., the region between the dual channel gas distribution plate 316 and the pedestal 350). The RF electric field ionizes the process gas(es) from a gas source 337 into a plasma in the second plasma excitation region 318. The gas source 337 is in fluid communication with the second plasma excitation region 318 through the sidewall gas inlet 352, which is disposed at the sidewall 354 of the CCP unit 302. The second gas inlet 352 connects to the second set of channels 319 in the dual channel gas distribution plate 316.

In one implementation where a silicon-containing layer, for example silicon nitride, is to be formed on the substrate, the gas source 337 may include a silicon-containing precursor and a nitrogen-containing precursor. Suitable silicon-containing precursor may include silanes, halogenated silanes, organosilanes, and any combinations thereof. Silanes may include silane (SiH₄) and higher silanes with the empirical formula SiₓH₍₂ₓ₊₂₎, such as disilane (Si₂H₆), trisilane (Si₃H₈), and tetrasilane (Si₄H₁₀), or other higher order silanes such as polychlorosilane. Suitable nitrogen-containing precursor may include nitrogen (N₂), nitrous oxide (N₂O), nitric oxide (NO), nitrogen dioxide (NO₂), ammonia (NH₃), and any combination thereof. In one implementation, the silicon-containing precursor is SiH₄ and the nitrogen-containing precursor is NH₃.

A second electrical insulator 356, similar to the electrical insulator 108 as discussed above with respect to FIG. 1, is disposed at the sidewall 354 below the dual channel gas distribution plate 316.

Likewise, radical containing precursor, such as nitrogen-containing radicals, is introduced into the second plasma excitation region 318 during deposition. Sequentially or concurrently, a second gas, such as a gas mixture of a silicon-containing precursor (e.g., SiH₄) and a nitrogen-containing precursor (e.g., NH₃), is introduced from the gas source 337 to the second plasma excitation region 318 through the sidewall gas inlet 352. The excitation of the second gas may produce SiH₃, SiH₂, SiH, NH₂, and NH etc. in ionic state in the second plasma excitation region 318. Similar to those discussed above with respect to FIGS. 1 and 2, the radical nitrogen species generated from the in-situ plasma source unit 304 can react preferentially with silicon due to lower Si—Si bond energies as compared to Si—N bond energies. The radical nitrogen species can also react with hydrogen because the SiH₃—H bond energies is lower than NH₂—H bond energies. Therefore, the amount of hydrogen available to the surface reaction of silicon nitride is reduced. The addition of the radical nitrogen species to the excited gas mixture using the configuration of FIG. 3 can encourage replacement of the Si—H bonds with Si—N and N—H bonds, which in turn reduces the concentration of Si—H bonds in the deposited SiN film. As a result, the deposited SiN film can be formed with lower intrinsic stress. The incorporation of the nitrogen radical source (i.e., in-situ plasma source unit 304) to the CCP unit 302 within the processing system 300 significantly increase the deposition rate of the SiN film since more radical nitrogen species are provided in the second plasma excitation region 318 for the surface reaction.

In summary, implementations of the disclosure provide an improved plasma processing system incorporating a RPS unit with a CCP unit for substrate processing. By using a RPS unit to deliver abundant nitrogen radical species to the excited gas mixture in plasma excitation region within the CCP unit, the Si—H bonds can be replaced with Si—N and N—H bonds, which in turn reduces the concentration of Si—H bonds in the deposited SiN film. Lower Si—H bonds lead to lower intrinsic stress in the deposited SiN film. As a result, the deposited SiN film is formed with improved film quality. The addition of the nitrogen radical species to the gas reaction can also increase the deposition rate of the SiN film since more radical nitrogen species are provided in the plasma excitation region for the surface reaction.

While the foregoing is directed to implementations of the present disclosure, other and further implementations of the disclosure may be devised without departing from the basic scope thereof, and the scope thereof is determined by the claims that follow.

1. A substrate processing system, comprising:
a plasma source unit, comprising:
a lid;
a gas distribution plate disposed below the lid, the gas distribution plate having a plurality of through holes arranged across the diameter of the gas distribution plate; and
a pedestal disposed below the gas distribution plate, wherein the pedestal and the gas distribution plate define a plasma excitation region therebetween;
a first remote plasma source (RPS) unit having a first gas outlet coupled to a first gas inlet disposed at the lid, wherein the first gas outlet is in fluid communication with the plasma excitation region; and
a second RPS unit having a second gas outlet coupled to a second gas inlet disposed at the lid, wherein the second gas outlet is in fluid communication with the plasma excitation region, and the second RPS unit has an ion filter disposed between the second gas outlet and the second gas inlet of the lid.

2. The substrate processing system of claim 1, wherein the plasma source unit is a capacitively coupled plasma (CCP) unit, an inductively coupled plasma (ICP) source, or a plasma source using low-pressure or atmospheric pressure discharge.

3. The substrate processing system of claim 2, wherein the plasma source unit is a capacitively coupled plasma (CCP) unit.

4. The substrate processing system of claim 1, wherein the first RPS is connected to a first gas source comprising fluorine.

5. The substrate processing system of claim 1, wherein the second RPS is connected to a second gas source comprising nitrogen.

6. The substrate processing system of claim 1, further comprising:
a third gas inlet disposed at the lid, wherein the third gas inlet is in fluid communication with a third gas source comprising a silicon-containing precursor and a nitrogen-containing precursor.

7. The substrate processing system of claim 6, wherein the silicon-containing precursor comprises silanes, halogenated silanes, organosilanes, or combinations thereof.

8. The substrate processing system of claim 6, wherein the nitrogen-containing precursor comprises nitrogen (N₂), nitrous oxide (N₂O), nitric oxide (NO), nitrogen dioxide (NO₂), ammonia (NH₃), or combinations thereof.

9. A substrate processing system, comprising:
a plasma source unit, comprising:
a lid; and
a dual channel gas distribution plate disposed below the lid, the dual channel gas distribution plate having:
a first set of channels that traverse the thickness of the dual channel gas distribution plate, wherein the first set of channels is arranged across the diameter of the dual channel gas distribution plate; and
a second set of channels disposed within the dual channel gas distribution plate, wherein the second set of channels traverse a portion of the thickness of the dual channel gas distribution plate;
a pedestal disposed below the dual channel gas distribution plate, wherein the pedestal and the dual channel gas distribution plate define a plasma excitation region therebetween;
a first remote plasma source (RPS) unit having a first gas outlet coupled to a first gas inlet disposed at the lid, wherein the first gas outlet is in fluid communication with the plasma excitation region; and
a second RPS unit having a second gas outlet coupled to a second gas inlet disposed at the lid, wherein the second gas outlet is in fluid communication with the plasma excitation region, and the second RPS unit has an ion filter disposed between the second gas outlet and the second gas inlet of the lid.

10. The substrate processing system of claim 9, wherein the plasma source unit is a capacitively coupled plasma (CCP) unit, an inductively coupled plasma (ICP) source, or a plasma source using low-pressure or atmospheric pressure discharge.

11. The substrate processing system of claim 9, wherein the first RPS is connected to a first gas source comprising fluorine.

12. The substrate processing system of claim 9, wherein the second RPS is connected to a second gas source comprising nitrogen.

13. The substrate processing system of claim 9, wherein the second set of channels is fluidly coupled to a third gas source through a sidewall gas inlet disposed at a sidewall of the plasma source unit.

14. The substrate processing system of claim 13, wherein the third gas source comprises a silicon-containing precursor and a nitrogen-containing precursor, wherein the silicon-containing precursor comprises silanes, halogenated silanes, organosilanes, and any combinations thereof, and the nitrogen-containing precursor comprises nitrogen (N₂), nitrous oxide (N₂O), nitric oxide (NO), nitrogen dioxide (NO₂), ammonia (NH₃), and any combinations thereof.

15. A substrate processing system, comprising:
a lid;
a gas distribution plate disposed relatively below the lid, the gas distribution plate having a plurality of through holes arranged across the diameter of the gas distribution plate;
an ion suppression element disposed relatively below the gas distribution plate, the ion suppression element having a plurality of through holes each having a tapered portion and a cylindrical portion, wherein the ion suppression element and the gas distribution plate define a first plasma excitation region;
a dual channel gas distribution plate disposed relatively below the ion suppression element, the dual channel gas distribution plate having:
a first set of channels that traverse the thickness of the dual channel gas distribution plate, wherein the first set of channels is arranged across the diameter of the dual channel gas distribution plate; and
a second set of channels disposed within the dual channel gas distribution plate, wherein the second set of channels traverse a portion of the thickness of the dual channel gas distribution plate;
a plasma suppressor disposed between the ion suppression element and the dual channel gas distribution plate, wherein the plasma suppressor has a plurality of through holes disposed across the diameter of the plasma suppressor;
a pedestal disposed below the dual channel gas distribution plate, wherein the pedestal and the dual channel gas distribution plate define a second plasma excitation region therebetween;
a first gas source coupled to a first gas inlet disposed at the lid, wherein the first gas inlet is in fluid communication with the first plasma excitation region; and
a second gas source coupled to a second gas inlet disposed at a sidewall of the substrate processing system.

16. The substrate processing system of claim 15, wherein each through hole of the plasma suppressor has a diameter of about 0.050″.

17. The substrate processing system of claim 15, wherein the lid and/or the gas distribution plate are coupled to a RF generator, and the ion suppression element is grounded.

18. The substrate processing system of claim 15, wherein the dual channel gas distribution plate is coupled to a RF generator, and the pedestal is grounded.

19. The substrate processing system of claim 15, wherein the first gas source comprising nitrogen.

20. The substrate processing system of claim 15, wherein the second gas source comprises a silicon-containing precursor and a nitrogen-containing precursor, wherein the silicon-containing precursor comprises silanes, halogenated silanes, organosilanes, and any combinations thereof, and the nitrogen-containing precursor comprises nitrogen (N₂), nitrous oxide (N₂O), nitric oxide (NO), nitrogen dioxide (NO₂), ammonia (NH₃), and any combinations thereof.
